(19) United States
(12) Patent Application Publication
(10) Pub. No.: US 2010/0276701 A1
(43) Pub. Date: Nov. 4, 2010

(54) LOW THERMAL RESISTANCE AND ROBUST CHIP-SCALE-PACKAGE (CSP), STRUCTURE AND METHOD

(76) Inventors: François Hébert, San Mateo, CA (US); Nikhil Kelkar, Saratoga, CA (US)

Correspondence Address: MH2 TECHNOLOGY LAW GROUP, LLP, 1951 KIDWELL DRIVE, SUITE 550, TYSONS CORNER, VA, 22182, US

(21) Appl. No.: 12/612,616

(22) Filed: Nov. 4, 2009

Related U.S. Application Data
(60) Provisional application No. 61/173,684, filed on Apr. 29, 2009.

(51) Int. Cl. H01L 29/26; H01L 21/00

(52) U.S. Cl. 257/77; 438/105; 257/E29.104; 257/E21.001

(57) ABSTRACT

A chip scale package (CSP) semiconductor device can include a semiconductor layer, circuitry on an active surface of the semiconductor layer, and a diamond layer on a back side of the semiconductor layer. The diamond layer can provide an efficient heat sink for the semiconductor layer, with a thermal conductivity which can be more than three times greater than the thermal conductivity of copper. Further, a hardness of the diamond layer (up to about 10 times stronger than silicon) can provide effective protection against damage to the exposed semiconductor layer, for example during manufacturing, handling, and use of the CSP device. Thus a thin protective diamond layer can be used, which can result in a very thin CSP package design.

### CROSS-REFERENCE TO RELATED APPLICATION

This application claims priority to provisional U.S. Patent Application Ser. No. 61/173,684 filed Apr. 29, 2009, the disclosure of which is herein incorporated by reference in its entirety.

### BACKGROUND OF THE INVENTION

Various semiconductor device package characteristics are considered when packaging a semiconductor die. Each package type has its advantages and disadvantages. A common semiconductor device package can include a semiconductor die mounted on a die pad of a device leadframe using epoxy or a die attach tape, then encapsulated in plastic resin. Encasing a semiconductor die in a ceramic package is also well known.

A packaged semiconductor device including a die encapsulated in plastic or encased in ceramic can be reliable but has a relatively large external package dimension. Thicker external package materials protect the die but add significantly to the X, Y, and Z dimensions of the completed device. Encapsulation, which includes the use of a leadframe, and ceramic packaging are also expensive and can add to manufacturing complexity. With decreasing device sizes other die packaging schemes have been used to decrease the size of the completed semiconductor device.

One package scheme, chip scale packages (CSP's), can include a thin passivation layer on the active side of the die with no other external protection. These packages have a small footprint and require a minimal amount of space on a receiving substrate such as a printed circuit board, but leave the chip more susceptible to contact damage during manufacture and use. Further, the absence of a leadframe die pad can reduce heat dissipation away from the die during device operation, which can lead to temperature-related device malfunctions.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 depicts a cross section of an inventive embodiment including a chip scale package (CSP) including a semiconductor layer with a diamond backing layer;

FIG. 2 is a cross section depicting a CSP including a diamond layer interposed between two semiconductor layers according to the present teachings;

FIG. 3 depicts a CSP device cross section including a semiconductor layer and a textured diamond backing layer according to the present teachings;

FIG. 4 is a cross section of a CSP device including a semiconductor layer and a grooved diamond backing layer according to the present teachings;

FIG. 5 is a plan view of a mask including marking indicia which can be used to form grooves in a diamond layer on a back side of a semiconductor layer according to the present teachings;

FIG. 6 is a cross section depicting a grooved semiconductor substrate and a conformal diamond backing layer which can be used to form a CSP device according to the present teachings; and

FIG. 7 is a chart depicting characteristics of various materials including diamond.

It should be noted that some details of the FIGS. have been simplified and are drawn to facilitate understanding of inventive embodiments rather than to maintain strict structural accuracy, detail, and scale.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts.

A chip scale package (CSP) can include an unpackaged semiconductor die and external dimensions of reduced size compared with packaged devices which use plastic resin encapsulation or ceramic housings. For purposes of the present application, an “unpackaged” device includes one which, prior to attachment to a receiving substrate such as a printed circuit board, is not encapsulated in a molded encapsulation material or encased in ceramic. A CSP device, however, is more susceptible to contact damage, both physical and electrical, during manufacture and use because the die is exposed or possibly covered with only a thin passivation layer. Further, the absence of a leadframe die pad in CSP packages reduces heat dissipation away from the die during device operation. A supplementary material used as a heat sink requires additional processing and materials, can significantly increase the size of the completed package, and therefore adds to the cost of the device.

Embodiments of the present teachings can include the use of one or more diamond layers formed over a back (i.e. noncircuit) side of a semiconductor substrate. Thermal properties of the diamond layer can result in dissipation of heat away from a die during device operation, and the hardness of a diamond layer can protect exposed surfaces of the semiconductor substrate. Additional processing of the diamond layer as discussed below can increase heat dissipation, and structural elements of the device can improve robustness against contact damage and provide marking indicia such as lot data or other device information. As further discussed below, the diamond layer can be formed to be either an electrical insulator or conductor.

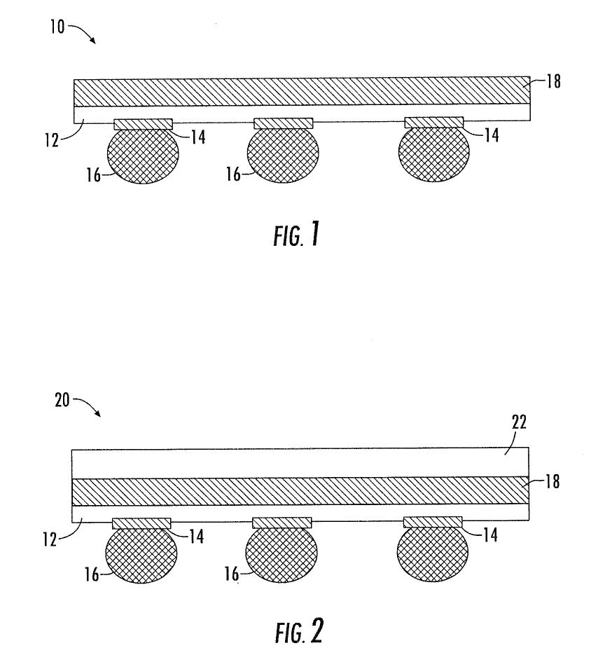

FIG. 1 depicts a CSP semiconductor device 10 including a semiconductor substrate 12 having a front surface (i.e. active surface or circuit side) including a metallization layer which forms interconnect terminals 14, conductive structures 16 which electrically couple the CSP device to a supporting substrate such as a printed circuit board (not depicted), and a diamond backing layer 18 on the back side of the semiconductor substrate 12. The semiconductor substrate 12 can include a semiconductor wafer, a portion of a semiconductor wafer, etc. The interconnect terminals 14 can include an under-ball metal layer and/or a barrier metal such as NiAu. The conductive structures 16 can include solder balls as depicted, and/or other connections such as solder bumps, copper bumps, copper columns, etc. which provide an electrical connection to the interconnect terminals 14.

The diamond layer 18 can be formed on the back of substrate 12 with a chemical vapor deposition (CVD) process, for example using a microwave, a plasma source, or thermal CVD using a tungsten filament. An atomic layer deposition (ALD) process, while slow, may be workable in some uses. Other processing techniques for forming a diamond layer are also contemplated. To enable nucleation, the wafers can be seeded, for example in a solution containing nanoparticles of diamond. Seeding can also be performed using a treatment of a thin tungsten layer or physical damage to the surface. Without diamond seeding, graphite particles can be deposited.

A large grain diamond crystal structure would have the advantage of high thermal conductivity, which would result in a highly effective heat sink layer. A diamond crystal structure including a nanocrystalline structure would have a grain size in the range of about 50 nanometers (nm) to about 100 nm. A microcrystalline diamond structure and a polycrystalline diamond structure can have a grain size which is about ½of the film thickness. The surface roughness of a diamond layer will typically be a fraction of the grain size, for example between about 0.1 micrometers (μm) to about 1.0 μm.

Either before or after forming the diamond layer on the noncircuit side of the wafer 12, the active surface of the semiconductor substrate can be processed to form device layers and/or circuitry thereon. Interconnects can be patterned, then metallization can be completed using a CSP-compatible metal, for example NiAu plated on the exposed interconnect terminals 14 such as bond pads.

The diamond backing layer on the back side of the semiconductor wafer can be marked to label each individual unsingularized die. Marking can be performed using a laser, by masking and etching the diamond using an oxygen-based process, using a ball drop process, stenciling, or using other techniques.

Subsequently, a separate passivation film can be applied to the diamond layer on the back of the wafer, additional processing to the front of the wafer can be performed, and then the wafer can be diced to form a plurality of completed semiconductor devices, such as CSP devices.

If formed as a dielectric layer, the diamond layer 18 can function as an electrical insulator. This would enable direct contact with the back side of the device with little or no risk of an electrical short.

In another embodiment, the diamond layer can be formed as a conductive layer, for example by doping with a p-type material (i.e. “P-doped”). In this use, the diamond layer 18 can reduce the electrical resistance of the semiconductor device, and can thus function in a similar capacity as a highly doped substrate or one or more buried layers. Doping the diamond layer with a P-type dopant such as boron, for example to a P-concentration of between about 1E17 atoms/cm³ and about 1E19 atoms/cm³, can have various advantages as described below. P+ doping in the range of from about 1E17 atoms/cm³ to 1E19 atoms/cm³ can be preferred for some applications to reduce voltage drop in the substrate which can result from device leakage.

It can be desirable to provide a thin silicon wafer 12 to decrease thermal resistance of the semiconductor wafer. Placing an electrical insulating material such as a dielectric on the back of the thinned silicon wafer, however, may worsen the risk of device “latch-up” between adjacent devices formed on the circuit side of the wafer. This occurs most often in devices using field isolation as opposed to trench isolation, and substrate current or leakage current in the substrate can result in a high voltage drop because of the thin silicon substrate. Using an electrically conductive diamond layer, for example formed by P-type dopant implantation, can reduce latch-up since the current in the substrate can flow to the heat sink instead of laterally between devices on the circuit side of the semiconductor wafer.

A diamond heat sink therefore has advantages over a metal heat sink, for example because it can be doped to the conductivity of the semiconductor wafer upon which it is formed and improve the electrical characteristics of the device in addition to providing a heat sink. The dopant concentration within the diamond layer can be performed while growing the diamond layer using CVD or ALD techniques. A boron dopant source such as trimethylboron (TMB) or diborane can be employed. The doping can be performed according to the doping of the semiconductor wafer on and within which the devices are formed. This advantage is not available with metal heat sinks, and thus the use of the diamond layer can be further beneficial.

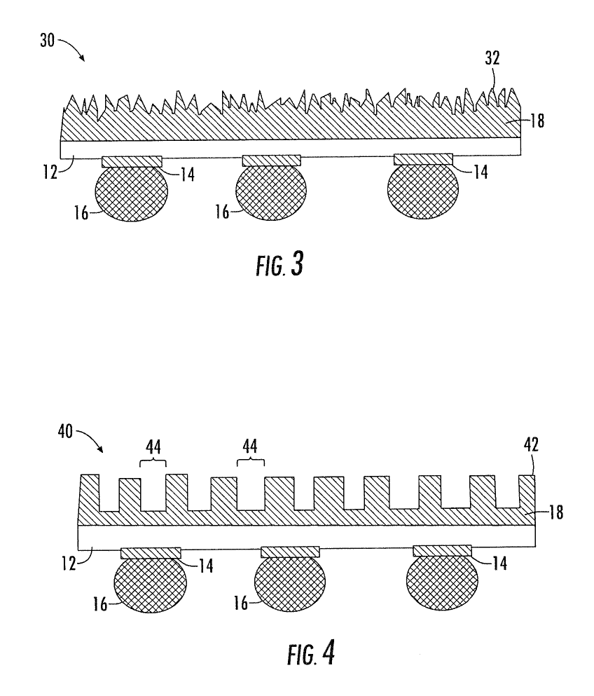

Another embodiment for forming a semiconductor device including a back side diamond layer can begin with the structure depicted in FIG. 2. This embodiment includes a device 20 having a silicon wafer 12, a diamond layer 18, and a silicon layer 22 on the back side of the diamond layer 18. The silicon layer 22 can be formed using various techniques, such as by using a method including a handle wafer. Handle wafer processing techniques are conventionally used with direct silicon bonding (DSB) processes, for example.

With the silicon-diamond-silicon substrate of FIG. 2, the diamond layer can be either conductive (for example, P-doped) or nonconductive, depending on the application. The circuit side of the silicon substrate 12 can be processed, for example to form a plurality of devices or partially completed devices, then an interconnect and finish metallization layer with a CSP-compatible metal can be performed. The finish metallization can include NiAu plated on top of exposed bond pads.

The back side semiconductor layer 22, such as a handle wafer as previously discussed, can be removed to expose the diamond layer 18, for example using grinding, etching, or a combination of both. An etch such as a plasma strip can be employed. Because of the hard nature of the diamond, various etches can be used to remove the handle wafer and leave the diamond layer relatively unetched, although etches including oxygen should be avoided when removing the handle wafer 22 to decrease damage to the remaining diamond layer 18.

Another embodiment is depicted in FIG. 3, which includes a device 30 having a diamond layer 32 including a textured surface. The textured surface increases the exposed surface area of the diamond, and may therefore increase the dissipation of heat away from the semiconductor substrate 12 of a functioning device. Processing can begin by performing active-surface processing on a silicon-diamond-silicon wafer, for example which has a handle wafer as a backside substrate similar to that depicted in FIG. 2. After processing the active surface, the handle wafer can then be removed to expose the diamond layer, then the diamond layer can be textured. Texturing can be performed by applying a patterned mask then etching the surface, or by exposing the entire surface to an etchant which etches along grain boundaries. Etching techniques used to remove photoresist such as an oxygen-based plasma can be used to texture a diamond layer. In another embodiment, if the deposited diamond film is polycrystalline or microcrystalline in nature, texturing can occur during its formation, for example because of the size of the grains, without the need of additional treatment or the use of a handle wafer. As previously described, a microcrystalline diamond structure and a polycrystalline diamond structure can have a grain size which is about ½ of the film thickness. The surface roughness of a diamond layer will typically be a fraction of the grain size, for example between about 0.1 micrometers (μm) to about 1.0 μm. Other processing in accordance with previous embodiments can be performed.

As described in previous embodiments, the diamond layer 32 of FIG. 3 can be formed as a dielectric layer to function as an electrical insulator, or as a conductively doped layer to reduce the electrical resistance of the semiconductor device. Thus the diamond layer can function in a similar capacity as a highly doped substrate or one or more buried layers.

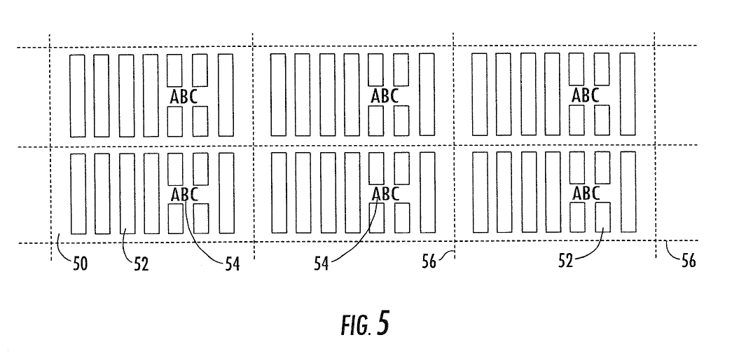

Another embodiment is depicted in FIG. 4, which includes a device 40 having a diamond layer 42 including one or more grooves 44 which form a textured surface. After performing processing of the active surface of the device and before metal deposition, the substrate can be background and polished using known techniques. A backside trench mask can be formed, which can include die marking (labeling) patterns. The diamond can then be etched, for example using an anisotropic etch including an oxygen-based etchant, to form grooves 44. The grooves form diamond “fins” which increase the exposed surface area of the diamond, and may therefore increase the dissipation of heat away from the semiconductor substrate 12 of a functioning device.

In the FIG. 4 structure, the patterned etch mask (for example photoresist, not individually depicted) used to etch the grooves 44 can be formed to provide a thicker diamond portion around the entire perimeter of the die as depicted. Chipping of the semiconductor substrate 12 can be most prevalent around the perimeter of the die. Forming a thick diamond portion around the entire perimeter of the die (defined by the perimeter of the wafer section 12) provides maximum protection against edge chipping. A thicker first portion of the diamond portion can be configured on the wafer by the patterned etch mask used to form the fins, while a second portion of the diamond layer is etched to a thinner profile to provide the plurality of grooves 44 as depicted in FIG. 4. A thick diamond portion can be formed on either side of a wafer scribe area prior to wafer dicing. Then, subsequent to wafer dicing, a thick diamond portion remains on either side of the scribe line such that a thick diamond “moat” is formed all around the perimeter of the die (such as that depicted in FIG. 5, described below), while fins provide an increased diamond surface area for improved heat dissipation away from the semiconductor wafer 12 over that which would be found with a flat diamond layer.

The diamond layer 42 of FIG. 4 can be formed as either a dielectric layer or as a conductive layer, as previously described. Thus the diamond layer can function in a similar capacity as a highly doped substrate or one or more buried layers. Other processing, for example in accordance with previous embodiments, can also be performed.

FIG. 5 depicts a patterned mask 50 formed over a diamond layer (not individually depicted) on a surface of a semiconductor wafer which can be used to etch the diamond layer to form grooves similar to those depicted in FIG. 4. The mask 50 includes a plurality of first openings 52 which expose the diamond layer to form a plurality of grooves and fins, and can further include a plurality of second openings 54 which can be used to form etched indicia within the diamond layer. The indicia can be used to label the completed devices with information such as lot or processing information, part numbers, copyright or patent information, etc. The pattern can be optimized to reduce or eliminate chipping and damage to the completed dies, for example by ensuring the edges of the semiconductor substrate are protected by the thicker diamond layer. For example, the mask 50 provides a thick diamond layer portion along the wafer scribe areas (i.e. saw kerfs or streets) 56 along which a the semiconductor substrate such as a semiconductor wafer can be cut using a dicing saw to singularize the wafer into a plurality of semiconductor dies. After removing the mask 50 and dicing the wafer, a thick diamond layer can remain around the entire perimeter of the die to provide a first diamond layer portion (a “moat” at previously described) which protects the edge of the die against chipping. The diamond layer can further include a second portion within the perimeter of the first portion which provides a plurality of fins which increases the surface area of the diamond layer to improve heat dissipation.

To etch the grooves and/or indicia, an etch including an oxygen-based etchant can be used. The grooves and/or indicia can also be formed using laser ablation to etch the diamond. A ball drop process, stenciling, or other techniques can also be used.

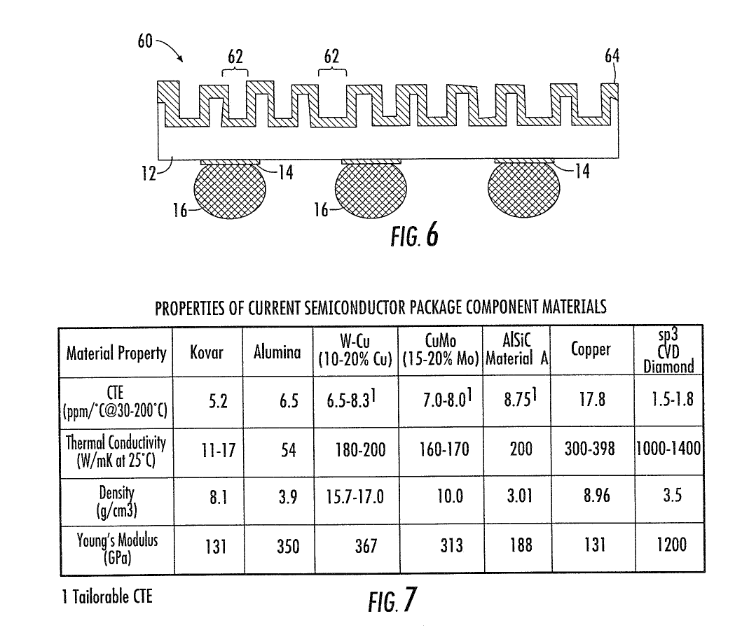

FIG. 6 depicts an embodiment of a device 60 in which the back side of the semiconductor substrate 12 is etched to form a plurality of grooves 62 and fins to increase the surface area of a subsequently formed diamond layer to improve heat dissipation away from the semiconductor wafer 12. As depicted in FIG. 6, the semiconductor substrate 12 has a perimeter which defines a perimeter of a semiconductor die. A conformal diamond layer 64 formed over the back side of the grooved substrate, for example using CVD or ALD processing techniques, improves heat dissipation away from the wafer 12. Prior to forming the diamond layer 64, the semiconductor substrate 12 can be formed up to the point of contact formation, prior to metal deposition. The back side of the wafer can be ground and polished. Then the back side can be masked and etched to groove the semiconductor substrate. After mask removal, the conformal diamond layer can then be formed over the grooves to provide a heat sink and heat spreader material for the completed semiconductor device. Other processing in accordance with previous embodiments can be performed.

Thus in use, the diamond backing layer or coating on the back side of a device such as a CSP device can be used to protect the device from damage and to draw heat away from a functioning substrate and dissipate the heat. Because diamond is a hard, strong material, a thin layer can be formed to minimize the size of the completed device. Further, the diamond is a semiconductor, and its electrical properties can be changed for use as a conductor or an insulator. The material can be doped, generally with a P-type material during an in situ process, during deposition or growth. N-type doping of the layer is also contemplated.

Silicon on diamond (SOD) wafers can be purchased from various vendors such as SP3 Diamond Technologies of Santa Clara, Calif.

FIG. 7 is a chart depicting properties of various materials, including diamond. The thermal conductivity of diamond is about three times better than copper. Further, its strength is about ten times that of silicon, thus it can be about ten times thinner for the same strength.

Thus with embodiments of the present invention, various chip scale package designs are contemplated. Devices and/or circuits can be formed in a substrate which includes a layer of silicon and a layer of diamond, or which includes a diamond layer interposed between two silicon layers. The diamond can be either nonconductive or conductive, depending on the eventual use. The diamond structure can have a polycrystalline structure with large grains to maximize thermal conductivity. The back side of the wafer opposite the electrical connections can be either exposed diamond (conductive or insulative) or exposed silicon, for example silicon formed as part of a handle wafer. Thus the diamond layer can function as a heat spreader and a head sink layer which can have the same size and shape as the semiconductor device layer, and which is in close proximity to the circuit devices, for example less than 50 microns away, and possibly less than 20 microns away.

In another embodiment, a diamond layer can be deposited on a handle substrate, then GaN as a device quality layer can be grown directly on the diamond layer. This can include the use of a seed layer such as silicon, sapphire, or silicon carbide. In another embodiment, diamond can be grown or deposited on a GaN substrate. Then the GaN can be thinned down by etching, chemical mechanical planarizing, or a grinding process.

A device including an embodiment of the present teachings can include one or more of various elements, including the following:

1) Electrodes on the active surface of the semiconductor layer of the die with circuitry. The electrodes can allow input/output signals, power and ground, etc. between the CSP semiconductor device and an electronic device using the CSP device.

2) A strong package which does not require encapsulation or metal leadframe to protect the sensitive circuitry formed on a semiconductor layer. A diamond layer provides structural integrity to the more fragile semiconductor layer, such as a silicon crystal layer. A diamond layer is up to ten times stronger than a silicon layer of similar thickness, thus allowing for a thinner device compared to a CSP device including only a silicon substrate or including a silicon substrate and an added heat sink layer.

3) A package with very low thermal resistance between the circuitry and a device to which the package is attached. This can result from the close physical proximity of the heat sink (diamond) to the structures which generate the heat (the circuitry on the semiconductor layer, for example). While prior techniques place the heat source up to hundreds of microns away from a separate heat sink layer, embodiments of the present teachings can place the circuitry within microns of the diamond heat sink layer.

4) A diamond layer used as a heat spreader which dissipates heat from localized hot spots in the circuitry over the entire area of the chip.

5) A diamond layer used as a heat sink to dissipate the heat from the circuitry to the surrounding environment (to air or another nearby heat sink structure).

6) A diamond layer which can be patterned, textured, or shaped to improve its mechanical and thermal properties. For example, diamond fins can be provided to improve heat dissipation, and a finned diamond can be thicker around the entire perimeter of the die to provide improved robustness against chipping of the edge of the semiconductor die.

7) A diamond layer which can be nanocrystalline, microcrystalline, polycrystalline, a nanocrystalline layer formed on a silicon surface followed by formation of one or more microcrystalline or polycrystalline layers.

Microcrystalline and polycrystalline films can have a roughness equivalent to the grain size of the diamond material without requiring additional processing to texture the material to increase its surface area.

8) Metal electrodes on the surface where the circuitry is formed can include solder balls, copper pillars, etc.

9) The back side of a silicon layer and/or a diamond layer can be patterned to maximize the thickness at the edges of the die to minimize breakage during testing, assembly, use, or during other handling of the device.

10) The diamond can be textured to maximize opacity, for example to reduce or eliminate light from reaching the circuitry. This can result, for example, from using nanocrystalline grains within the diamond layer. Further, the diamond layer can be formed such that the crystalline structure is optimized for specific thermal characteristics for a particular use of the diamond layer.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A semiconductor device, comprising:
a semiconductor layer having a front side and a back side;
circuitry on the front side of the semiconductor layer; and
a diamond layer disposed on the back side of the semiconductor layer such that the semiconductor layer and the diamond layer remain unpackaged during use of the semiconductor device.

2. The semiconductor device of claim 1, further comprising:
the semiconductor layer having a perimeter, wherein the semiconductor layer provides a portion of a semiconductor die defined by the perimeter of the semiconductor layer; and
the diamond layer on the back side of the semiconductor layer comprises:
a first portion having a first thickness which extends around the entire perimeter of the semiconductor layer;
a second portion having a second thickness which is less than the first thickness; and
a plurality of vertically oriented fins.

3. The semiconductor device of claim 2, wherein the diamond layer on the back side of the semiconductor layer further comprises etched marking indicia.

4. The semiconductor device of claim 2, further comprising a passivation layer on at least the front side of the semiconductor layer.

5. The semiconductor device of claim 2 wherein the semiconductor layer is a first semiconductor layer and the semiconductor device further comprises a second semiconductor layer, wherein the diamond layer is interposed between the first semiconductor layer and the second semiconductor layer.

6. The semiconductor device of claim 2 wherein the diamond layer is textured.

7. The semiconductor device of claim 1 wherein the diamond layer is doped to increase its electrical conductivity.

8. The semiconductor device of claim 1, wherein the semiconductor device is a chip scale package (CSP) device.

9. The semiconductor device of claim 1, further comprising:
a plurality of the interconnect terminals electrically connected to the circuitry on the front side of the semiconductor layer; and
a plurality of solder bumps, with each solder bump electrically connected with one of the interconnect terminals on the front side of the semiconductor layer.

10. The semiconductor device of claim 1, further comprising:
a plurality of the interconnect terminals electrically connected to the circuitry on the front side of the semiconductor layer; and
a plurality of copper columns, with each copper column electrically connected with one of the interconnect terminals on the front side of the semiconductor layer.

11. The semiconductor device of claim 1, further comprising:
a plurality of the interconnect terminals electrically connected to the circuitry on the front side of the semiconductor layer; and
a plurality of conductive structures, with each conductive structure electrically connected with one of the interconnect terminals on the front side of the semiconductor layer, wherein the plurality of conductive structures are selected from the group consisting of solder balls and copper bumps.

12. A method of forming an unpackaged semiconductor device, comprising:
providing a semiconductor device assembly comprising:
a semiconductor layer having an active surface and a back side; and
a diamond layer on a back side of the semiconductor layer;
forming circuitry on the active surface of the semiconductor layer such that there is no packaging on the semiconductor device during use of the semiconductor device.

13. The method of claim 12, further comprising:
the semiconductor layer having a perimeter which defines a perimeter of a semiconductor die; and
etching the diamond layer on the back side of the semiconductor layer to form a first diamond layer portion having a first thickness which extends around the entire perimeter of the semiconductor die, and to form a second diamond layer portion having a second thickness which is less than the first thickness.

14. The method of claim 13 wherein etching of the diamond layer forms a plurality of fins within the diamond layer.

15. The method of claim 13 further comprising forming a passivation layer on at least the active surface of the semiconductor layer.

16. The method of claim 12 wherein the semiconductor layer is a first semiconductor layer and the method further comprises providing a second semiconductor layer such that the diamond layer is interposed between the first semiconductor layer and the second semiconductor layer.

17. The method of claim 12 further comprising forming a textured diamond layer.

18. A method for forming an unpackaged semiconductor device, comprising:
providing a semiconductor device assembly comprising:
a semiconductor layer having an active surface and a back side;
a diamond layer on a back side of the semiconductor layer; conductively doping the active surface of the semiconductor layer;
forming circuitry on the active surface of the semiconductor layer; and
conductively doping the diamond layer on the back side of the semiconductor layer; and
completing formation of the semiconductor device such that the diamond layer on the back side of the semiconductor layer remains unpackaged during use of the semiconductor device.

19. The method of claim 18, wherein conductively doping the diamond layer is performed using a p-type dopant.

20. The method of claim 19, further comprising forming field isolation on the active surface of the semiconductor layer.
